(19) United States
(12) Patent Application Publication
(10) Pub. No.: US 2007/0134884 A1
(43) Pub. Date: Jun. 14, 2007

(54) Isolation method of defining active fins, method of fabricating semiconductor device using the same and semiconductor device fabricated thereby

(75) Inventors: Keun-Nam Kim, Suwon-si (KR); Chul Lee, Seoul (KR); Eun-Suk Cho, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/488,584

(22) Filed: Jul. 18, 2006

(30) Foreign Application Priority Data
Dec. 14, 2005 (KR) 10-2005-0123188

(51) Int. Cl. H01L 21/76; H01L 29/00; H01L 21/4763

(52) U.S. Cl. 438/424; 257/E21.54; 257/510; 438/618

(57) ABSTRACT

An isolation method of defining active fins, a method of fabricating a semiconductor device using the same, and a semiconductor device fabricated thereby are provided. The method of fabricating a semiconductor device includes: preparing a semiconductor substrate; and forming a plurality of active fins having major and minor axes and two-dimensionally arrayed on the semiconductor substrate in directions of the major and minor axes. A liner pattern is formed on lower sidewalls of the active fins. An isolation layer is formed on the semiconductor substrate having the liner pattern, and the isolation layer exposes top surfaces of the active fins and a part of the active fins' sidewalls substantially parallel to the major axis. Parallel gate lines are formed to cover the top surfaces and the exposed sidewalls of the active fins, cross over the active fins, and run on the isolation layer.

### CROSS-REFERENCE TO RELATED APPLICATION

This application claims priority to Korean Patent Application No. 10-2005-0123188, filed on Dec. 14, 2005, the contents of which are incorporated herein by reference in their entirety.

### BACKGROUND OF THE INVENTION

1. Field of the Invention

The present invention relates to a semiconductor device, and more particularly, to an isolation method of defining active fins, a method of fabricating a semiconductor device using the same, and a semiconductor device fabricated thereby.

2. Description of the Related Art

Semiconductor devices widely adopt a discrete device such as a field effect transistor as a switching device. In the transistor, an operating speed of the device is determined by an on-current generated in a channel between a source and a drain. Generally, a gate electrode and the source/drain are formed in a device formation region, i.e., an active region, of a semiconductor substrate in order to form a planar-type transistor. A general planar-type transistor has a planar channel between the source and the drain. On-current of the planar-type transistor is in direct proportion to a width of the active region, and in inverse proportion to a distance between the source and the drain, i.e., a gate length. Accordingly, in order to raise the operating speed of the device by increasing the on-current, the gate length should be decreased and the width of the active region should be increased. In a planar-type transistor, however, increasing the width of the active region runs counter to recent trends toward higher device integration.

Also, a short channel effect may occur as an interval between the source and the drain becomes narrower in the planar-type transistor. Consequently, the short channel effect must be effectively suppressed in order to realize a next generation transistor having a short channel length.

However, a conventional planar-type transistor is a planarized channel device, which has a channel parallel to a surface of a semiconductor. Thus, it is not only disadvantageous for downsizing a device, but also difficult to restrain the short channel effect.

A double gate field effect transistor (FET), which enables an electric potential of a channel to be effectively adjusted by positioning gates at both sides thereof, has been suggested as a device structure for replacing the conventional planar-type transistor. Moreover, in order to manufacture a double gate FET having front/back-side gates using a conventional semiconductor fabrication process without modification, a Fin-FET device has been proposed. In a semiconductor device in which Fin-FET devices are two-dimensionally disposed to have a certain regularity, such as in a cell region of a semiconductor memory device, the Fin-FET devices may be formed at a plurality of active fins insulated by an isolation layer formed using a trench isolation technique. Here, the isolation layer may expose sidewalls of an upper region of the active fins. Also, the plurality of Fin-FET devices may be electrically connected to a single gate line, i.e., a word line to constitute a circuit using the Fin-FET devices. That is, a plurality of word lines are provided, and the plurality of Fin-FET devices may be electrically connected to one word line

Moreover, each of the word lines may be formed to pass through active fins which are not electrically related in order to facilitate design and simplify a manufacturing process. That is, the word lines may be spaced apart from exposed sidewalls of electrically unrelated active fins by a gate dielectric layer, and thereby increase electric potential in the electrically unrelated active fins. This can cause degradation of current drivability of the Fin-FET devices. A method of fabricating such Fin-FET devices is disclosed in U.S. Patent Publication No. 2005/0153490 A1 to Yoon et al., entitled “Method of Forming Fin Field Effect Transistor”. The method of Yoon et al. includes forming fin-type active regions and an isolation layer enclosing the active regions on a semiconductor substrate. Yoon et al. illustrate gate electrodes passing through both electrically related and unrelated active regions. Here, the gate electrodes pass through the electrically unrelated active regions and cover the sidewalls of the active regions. As a result, the gate electrodes locally increase the electric potential in electrically unrelated active regions and thus can cause degradation of the electrical properties of the Fin-FET device.

### SUMMARY OF THE INVENTION

The present invention provides a method of fabricating a semiconductor device which uses an isolation method defining active fins, and a semiconductor device fabricated thereby.

In one aspect, the present invention is directed to a method of fabricating a semiconductor device, comprising: preparing a semiconductor substrate; forming a plurality of active fins having major and minor axes and two-dimensionally arrayed on the semiconductor substrate in directions of the major and minor axes; forming a liner pattern on lower sidewalls of the active fins; forming an isolation layer on the semiconductor substrate having the liner pattern, the isolation layer exposing top surfaces of the active fins and a part of the active fins' sidewalls substantially parallel to the major axis; and forming gate lines parallel to each other to cover the top surfaces and the exposed sidewalls of the active fins, cross over the active fins, and run on the isolation layer.

In one embodiment, the step of forming the liner pattern comprises: forming a preliminary insulating liner on the semiconductor substrate having the active fins; forming a preliminary trench insulating layer surrounding the active fins on the semiconductor substrate having the preliminary insulating liner; partially etching the preliminary trench insulating layer disposed between the sidewalls of the active fins parallel to the minor axis, thereby forming a trench insulating layer having a hole exposing a predetermined region of the preliminary insulating liner; removing the exposed preliminary insulating liner, thereby forming an insulating liner exposing upper sidewalls of the active fins substantially parallel to the minor axis; forming a preliminary buffer insulating pattern to fill a space between the upper sidewalls of the active fins substantially parallel to the minor axis on the semiconductor substrate having the insulating liner; and partially etching the insulating liner using the trench insulating layer and the preliminary buffer insulating pattern as etch masks.

In another embodiment, the step of forming the trench insulating layer comprises: forming a mask pattern having an opening which exposes the preliminary trench insulating layer disposed between the sidewalls of the active fins substantially parallel to the minor axis on the semiconductor substrate having the preliminary trench insulating layer; partially etching the exposed preliminary trench insulating layer using the mask pattern as an etch mask; and removing the mask pattern.

In another embodiment, the step of forming the isolation layer comprises isotropically etching the trench insulating layer and the preliminary buffer insulating pattern.

In another embodiment, the step of forming the liner pattern comprises: forming a preliminary insulating liner on the semiconductor substrate having the active fins; forming a preliminary trench insulating layer surrounding the active fins on the semiconductor substrate having the preliminary insulating liner; partially etching the preliminary trench insulating layer, thereby forming a trench insulating layer exposing the preliminary insulating liner disposed on upper sidewalls of the active fins substantially parallel to the minor axis and a part of the sidewalls of the active fins substantially parallel to the major axis; removing the exposed preliminary insulating liner and forming an insulating liner exposing predetermined regions of the sidewalls of the active fins; forming a preliminary buffer insulating pattern to cover the exposed sidewalls of the active fins on the semiconductor substrate having the insulating liner; and partially etching the insulating liner using the preliminary buffer insulating pattern and the trench insulating liner as etch masks.

In another embodiment, forming the trench insulating layer comprises: forming parallel mask patterns to cross the sidewalls of the active fins substantially parallel to the major axis on the semiconductor substrate having the preliminary trench insulating layer, cross over the active fins, and run on the preliminary trench insulating layer disposed on the sidewalls of the active fins substantially parallel to the minor axis; partially etching the preliminary trench insulating layer using the mask patterns as etch masks; and removing the mask patterns.

In another embodiment, the mask patterns are formed of photoresist patterns or hard mask patterns.

In another embodiment, forming the mask patterns from hard mask patterns comprises: forming preliminary hard mask patterns to have a first width on the semiconductor substrate having the preliminary trench insulating layer; and isotropically etching the preliminary hard mask patterns, thereby forming the mask patterns to have a smaller width than the first width.

In another embodiment, forming the isolation layer comprises isotropically etching the preliminary buffer insulating pattern and the trench insulating layer.

In another embodiment, the isolation layer is formed of a material layer having an etch selectivity with respect to the liner pattern.

In another embodiment, the liner pattern is formed of a silicon nitride layer, and the isolation layer is formed of a silicon oxide layer.

In another embodiment, the method further comprises, after forming the active fins, forming a buffer oxide layer covering the sidewalls of the active fins, wherein the buffer oxide layer covering upper sidewalls of the active fins substantially parallel to the major axis is removed in forming the isolation layer.

In another embodiment, the isolation layer disposed between the sidewalls of the active fins substantially parallel to the minor axis is formed to have a top surface on substantially the same level as the top surfaces of the active fins.

In another embodiment, the method further comprises, before forming the gate line, forming a gate dielectric layer to cover the top surfaces and the exposed sidewalls of the active fins.

In another aspect, the present invention is directed to a method of fabricating a semiconductor device, comprising: forming a plurality of active fins on a semiconductor substrate; forming a liner pattern surrounding lower sidewalls of the active fins; forming a gate dielectric layer surrounding higher sidewalls of the active fins, the gate dielectric layer covering the top surfaces of the active fins; forming an isolation layer on the liner pattern; forming gate lines on the gate dielectric layer, the gate lines crossing over the active fins and extended to the top of the isolation layer.

In one embodiment, some portions of the gate lines are interposed between the gate dielectric layer and the isolation layer.

In another embodiment, the method further comprises forming a buffer oxide layer between the lower sidewalls of the active fins and the liner pattern.

In another embodiment, the isolation layer is formed of a trench insulating pattern and a buffer insulating pattern, the trench insulating pattern disposed below the buffer insulating pattern.

In another embodiment, a portion of the buffer insulating pattern contacts with the liner pattern and the gate lines.

In another embodiment, the isolation layer is formed of a silicon oxide layer.

In another embodiment, the liner pattern is formed of a silicon nitride layer.

In another aspect, the present invention is directed to a semiconductor device, comprising: a semiconductor substrate; a plurality of active fins having major and minor axes and two-dimensionally arrayed on the semiconductor substrate in directions of the major and minor axes; an isolation layer surrounding the active fins and exposing top surfaces of the active fins and a part of the active fins' sidewalls substantially parallel to the major axis; a liner pattern interposed between lower sidewalls of the active fins and the isolation layer; and gate lines covering the top surfaces of the active fins and the exposed sidewalls of the active fins, crossing over the active fins, and extended to the top of the isolation layer.

In one embodiment, the isolation layer is formed of a trench insulating pattern and a buffer insulating pattern, the trench insulating pattern partially exposing the sidewalls of the active fins substantially parallel to the major axis and filling spaces between the active fins to have recessed holes which expose upper sidewalls of the active fins substantially parallel to the minor axis between the sidewalls of the active fins substantially parallel to the minor axis, the buffer insulating pattern filling the recessed holes.

In another embodiment, the isolation layer disposed between the sidewalls of the active fins substantially parallel to the minor axis is composed of buffer insulating patterns covering upper sidewalls of the active fins substantially parallel to the minor axis, and a trench insulating pattern interposed between the buffer insulating patterns and between the lower sidewalls of the active fins substantially parallel to the minor axis.

In another embodiment, the isolation layer disposed between the sidewalls of the active fins substantially parallel to the minor axis has a top surface on substantially the same level as the top surfaces of the active fins.

In another embodiment, the isolation layer is formed of a silicon oxide layer and the liner pattern is formed of a silicon nitride layer.

In another embodiment, the device further comprises a gate dielectric layer interposed between the active fins and the gate line.

In another aspect, the present invention is directed to a semiconductor device comprising: a plurality of active fins on a semiconductor substrate; a liner pattern surrounding lower sidewalls of the active fins; a gate dielectric layer surrounding higher sidewalls of the active fins, the gate dielectric layer covering the top surfaces of the active fins; an isolation layer on the liner pattern; gate lines on the gate dielectric layer, the gate lines crossing over the active fins and extended to the top of the isolation layer.

In one embodiment, some portions of the gate lines are interposed between the gate dielectric layer and the isolation layer.

In another embodiment, the device further comprises a buffer oxide layer interposed between the lower sidewalls of the active fins and the liner pattern.

In another embodiment, the isolation layer is formed of a trench insulating pattern and a buffer insulating pattern, the trench insulating pattern disposed below the buffer insulating pattern.

In another embodiment, a portion of the buffer insulating pattern contacts with the liner pattern and the gate lines.

In another embodiment, the isolation layer is formed of a silicon oxide layer.

In another embodiment, the liner pattern is formed of a silicon nitride layer.

### BRIEF DESCRIPTION OF THE DRAWINGS

The foregoing and other objects, features and advantages of the invention will be apparent from the more particular description of exemplary embodiments of the invention, as illustrated in the accompanying drawings. The drawings are not necessarily to scale, emphasis instead being placed upon illustrating the principles of the invention.

FIG. 1 is a plan view of a semiconductor device according to an exemplary embodiment of the invention.

FIGS. 2 through 9 are cross-sectional views illustrating a method of fabricating a semiconductor device according to an exemplary embodiment of the invention.

FIG. 10 is a plan view of a semiconductor device according to another exemplary embodiment of the invention.

FIGS. 11 through 16 are cross-sectional views illustrating a method of fabricating a semiconductor device according to another exemplary embodiment of the invention.

### DETAILED DESCRIPTION OF THE INVENTION

The present invention will now be described more fully hereinafter with reference to the accompanying drawings, in which exemplary embodiments of the invention are shown. This invention may, however, be embodied in different forms and should not be construed as limited to the exemplary embodiments set forth herein. Rather, these exemplary embodiments are provided so that this disclosure will be thorough and complete, and will fully convey the scope of the invention to those skilled in the art. In the drawings, the thickness of layers and regions may be exaggerated for clarity, and like numbers refer to like elements throughout.

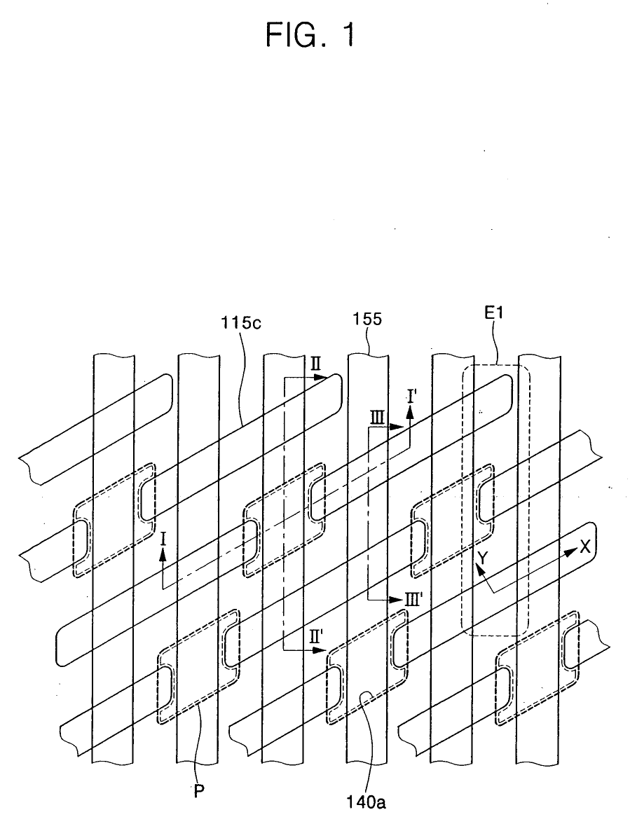

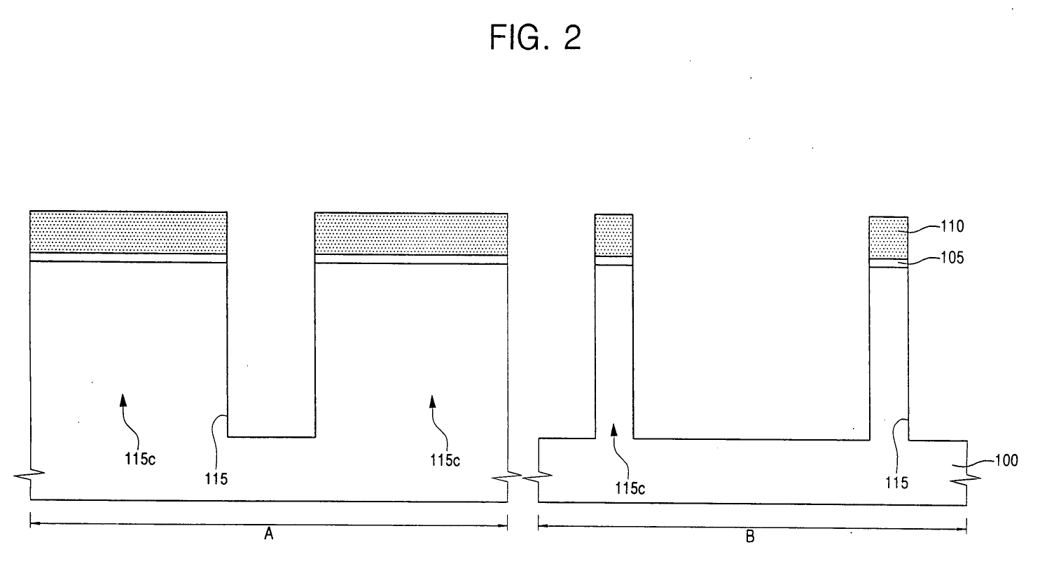

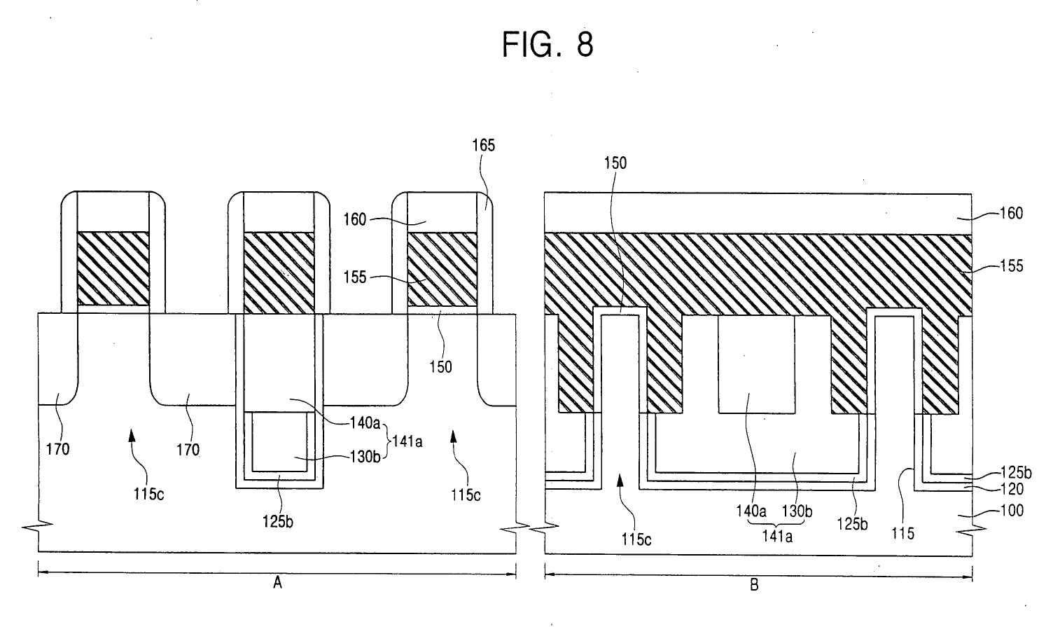

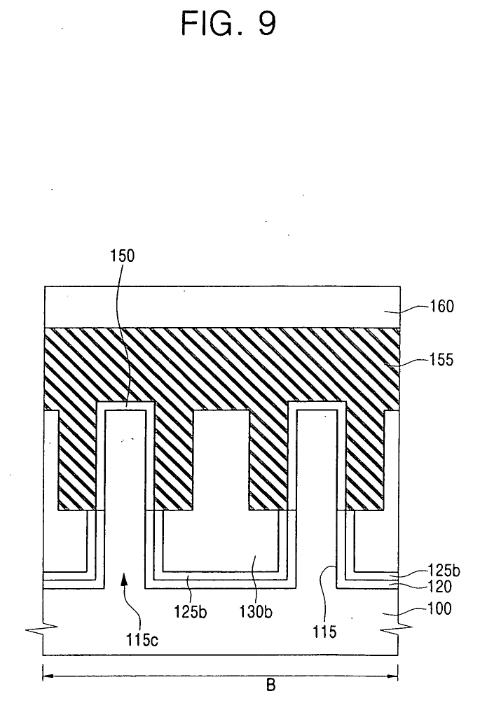

FIG. 1 is a plan view of a semiconductor device according to an exemplary embodiment of the invention, and FIGS. 2 through 9 are cross-sectional views illustrating a method of fabricating a semiconductor device according to an exemplary embodiment of the invention. In FIGS. 2 through 8, reference mark “A” denotes a cross-section taken along line I-I′ of FIG. 1, reference mark “B” denotes a cross-section taken along line II-II′ of FIG. 1, and FIG. 9 is a cross-sectional view taken along line III-III′ of FIG. 1.

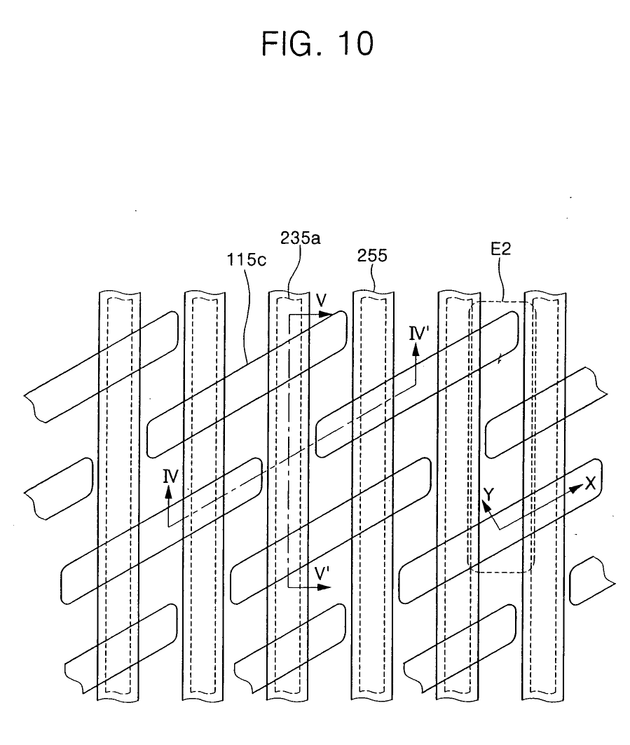

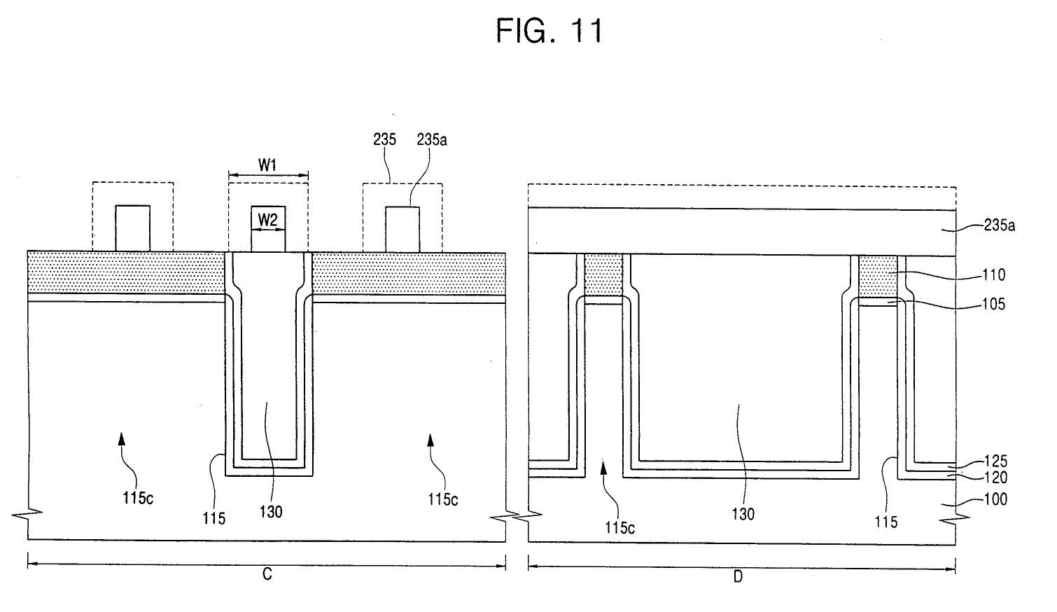

FIG. 10 is a plan view of a semiconductor device according to another exemplary embodiment of the invention, and FIGS. 11 through 16 are cross-sectional views illustrating a method of fabricating a semiconductor device according to another exemplary embodiment of the invention. In FIGS. 11 through 16, reference mark “C” denotes a cross-section taken along line IV-IV′ of FIG. 10, and reference mark “D” denotes a cross-section taken along line V-V′ of FIG. 10.

First, a method of fabricating a semiconductor device according to an exemplary embodiment of the invention will be described with reference to FIGS. 1 through 9.

Referring to FIGS. 1 and 2, a semiconductor substrate 100 having active regions and a field region adjacent thereto is prepared. The semiconductor substrate 100 may be, for example, an SOI substrate or a bulk silicon substrate. A plurality of active fins 115c is formed on the semiconductor substrate 100. The plurality of active fins 115c is two-dimensionally arrayed in directions of a major axis (X) and a minor axis (Y) on the semiconductor substrate 100. When the semiconductor substrate 100 is a bulk silicon substrate, capping masks may be formed to cover the active regions and expose the field region. Each capping mask may be formed of a stack of a pad oxide layer 105 and a hard mask 110 which are sequentially stacked. The pad oxide layer 105 may be formed of a thermal oxide layer. The hard mask 110 may be formed of a silicon nitride layer. The pad oxide layer 105 may be formed to reduce stress resulting from a difference in a thermal expansion coefficient between the semiconductor substrate 100 and the hard mask 110. The semiconductor substrate 100 is etched using the hard mask 110 as an etch mask, thereby forming a trench 115 in the semiconductor substrate of the field region. As a result, the plurality of active fins 115c defined by the trench 115 may be formed. Here, as shown in the plan view, the active fins 115c are two-dimensionally arrayed in the directions of the major and minor axes X and Y. Also, the active fins 115c may be formed of semiconductor fins. For example, the active fins 115c may be formed of silicon fins.

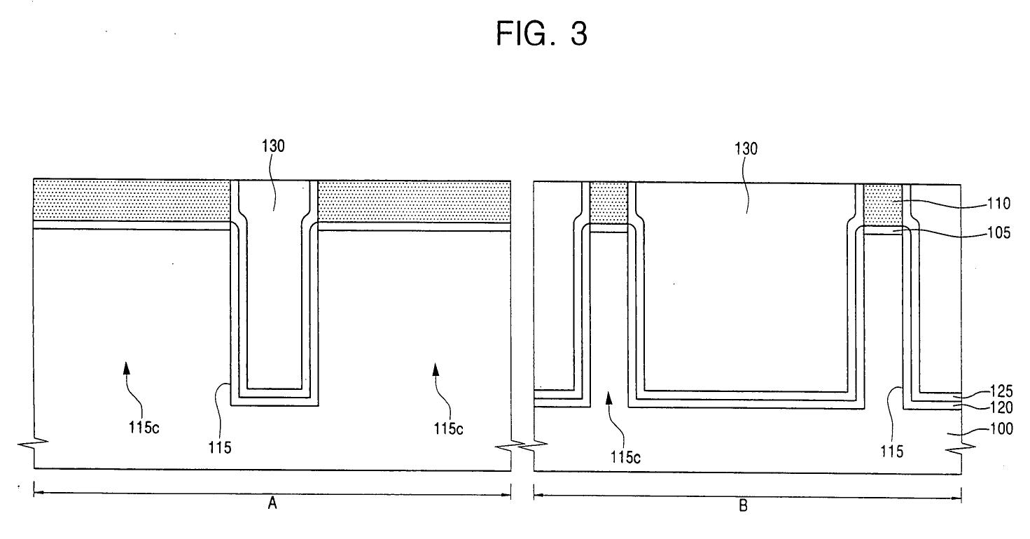

Referring to FIGS. 1 and 3, a buffer oxide layer 120 may be formed on sidewalls of the active fins 115c. When the active fins 115c are defined by forming the trench 115, a buffer oxide layer 120 may be formed on an inner wall of the trench 115. The buffer oxide layer 120 may be formed by thermal oxidation of the semiconductor substrate having the active fins 115c. For example, the buffer oxide layer 120 may be formed of a silicon oxide layer.

A preliminary insulating liner 125 is formed on the semiconductor substrate having the buffer oxide layer 120. The preliminary insulating liner 125 may be formed of a silicon nitride layer.

A preliminary trench insulating layer 130 surrounding the active fins 115c is formed on the semiconductor substrate having the preliminary insulating liner 125. In particular, an isolation insulating layer is formed on the semiconductor substrate having the preliminary insulating liner 125. Subsequently, the isolation insulating layer is planarized to fill the trench 115 covered with the preliminary insulating liner 125, and to form a preliminary trench insulating layer 130 having a top surface that is substantially the same level with the top surface of each hard mask 110. Here, the isolation insulating layer is planarized by a chemical mechanical polishing (CMP) technique using the preliminary insulating liner 125 covering the top surfaces of the hard masks 110 as a planarization stop layer.

In planarizing the isolation insulating layer, the preliminary insulating liner 125 disposed on the top surfaces of the hard masks 110 may be removed. As a result, the preliminary insulating liner 125 is formed to cover sidewalls of the hard masks 110 and the inner wall of the trench 115.

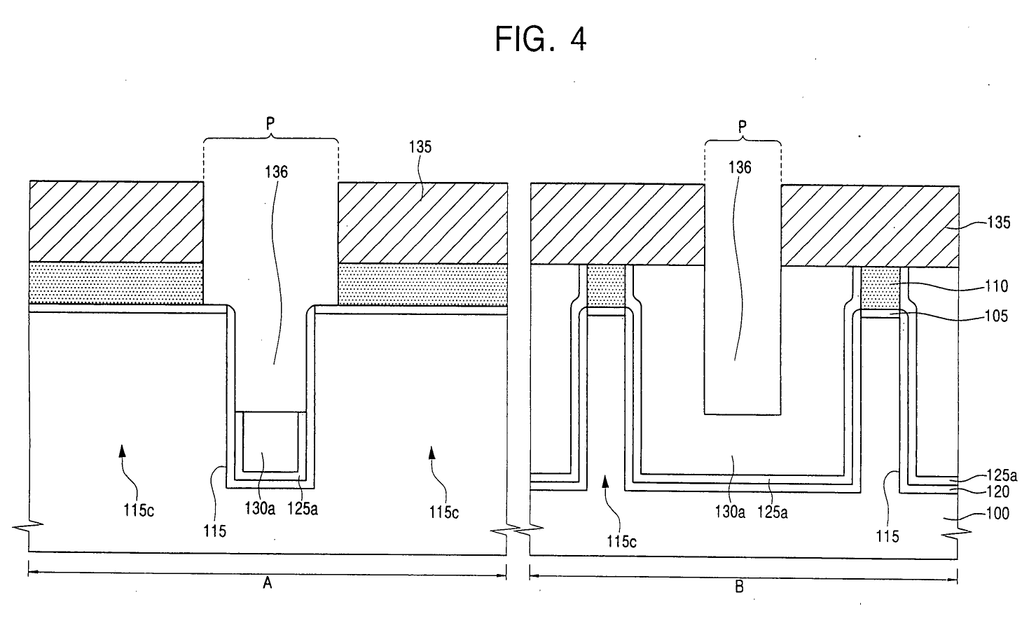

Referring to FIGS. 1 and 4, a mask pattern 135 may be formed on the semiconductor substrate having the preliminary trench insulating layer 130 to have openings P exposing the preliminary trench insulating layer (130 in FIG. 3) between the sidewalls of the active fins 115c, substantially parallel to the minor axis Y. The openings P of the mask pattern 135 may partially overlap the hard masks 110 covering the active fins 115c to expose predetermined regions of the hard masks 110. Likewise, the predetermined regions of the hard masks 110 exposed by the openings P may be determined in consideration of misalignment in photolithography and etching processes for forming the openings P. Further, the overlapping regions between the openings P and the hard mask patterns 110 may be determined in consideration of process margins of following processes.

The preliminary trench insulating layer (130 in FIG. 3) exposed by the openings P may be partially etched to form a hole exposing a predetermined region of the preliminary insulating liner (125 in FIG. 3). More specifically, the preliminary trench insulating layer (130 in FIG. 3) exposed by the openings P may be partially etched to form a trench insulating layer 130a having the hole exposing the predetermined region of the preliminary insulating liner (125 in FIG. 3). As a result, the preliminary insulating liner (125 in FIG. 3) on the upper sidewalls of the active fins 115c substantially parallel to the minor axis Y may be exposed. The trench insulating layer 130a, which is disposed between the sidewalls of the active fins 115c substantially parallel to the minor axis Y, may have a top surface on a lower level than the top surfaces of the active fins 115c.

Subsequently, the exposed preliminary insulating liner (125 in FIG. 3) may be removed by an etching process so as to form an insulating liner 125a. Accordingly, the insulating liner 125a may be formed on the semiconductor substrate between the active fins 115c, on the lower sidewalls of the active fins 115c substantially parallel to the minor axis Y, on the sidewalls of the active fins 115c substantially parallel to the major axis X, and on the sidewalls of the hard masks 110 substantially parallel to the major axis X.

Recessed holes 136 may be formed to expose the upper sidewalls of the active fins 115c substantially parallel to the minor axis Y. Bottoms of the recessed holes 136 may be disposed at a lower level than the top surfaces of the active fins 115c. Consequently, the buffer oxide layer 120 covering the upper sidewalls of the active fins 115c substantially parallel to the minor axis Y may be exposed.

The predetermined regions of the hard masks 110 exposed by the openings P may be etched during the formation of the insulating liner 125a so that the predetermined regions of the pad oxide layers 105 may be exposed.

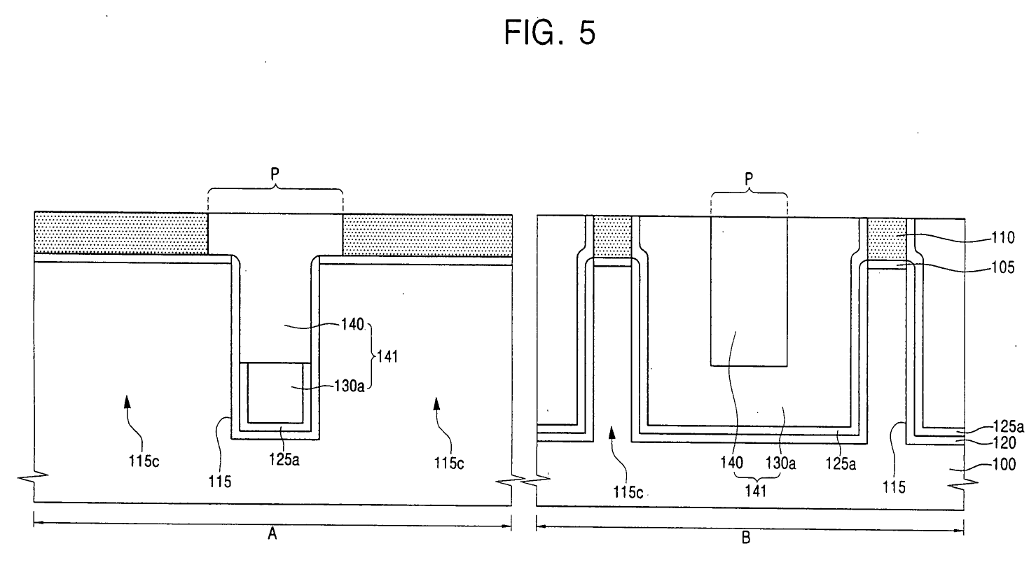

Referring to FIGS. 1 and 5, the mask pattern 135 may be removed. And, preliminary buffer insulating patterns 140 may be formed to fill the recessed holes 136. As a result, a preliminary isolation layer 141 may be formed of the preliminary buffer insulating patterns 140 and the trench insulating layer 130a. In particular, forming the preliminary buffer insulating patterns 140 may include forming a buffer insulating layer on the semiconductor substrate having the recessed holes 136, and planarizing the buffer insulating layer using the hard mask 110 as a planarization stop layer. Consequently, the preliminary buffer insulating pattern 140 may be formed to fill the recessed holes 136 and to have a top surface that is substantially the same level with the top surfaces of the hard masks 110. Accordingly, the top surfaces of the hard masks 110, and the predetermined region of the insulating liner 125a covering the sidewalls of the hard masks 110 substantially parallel to the major axis X, may be exposed.

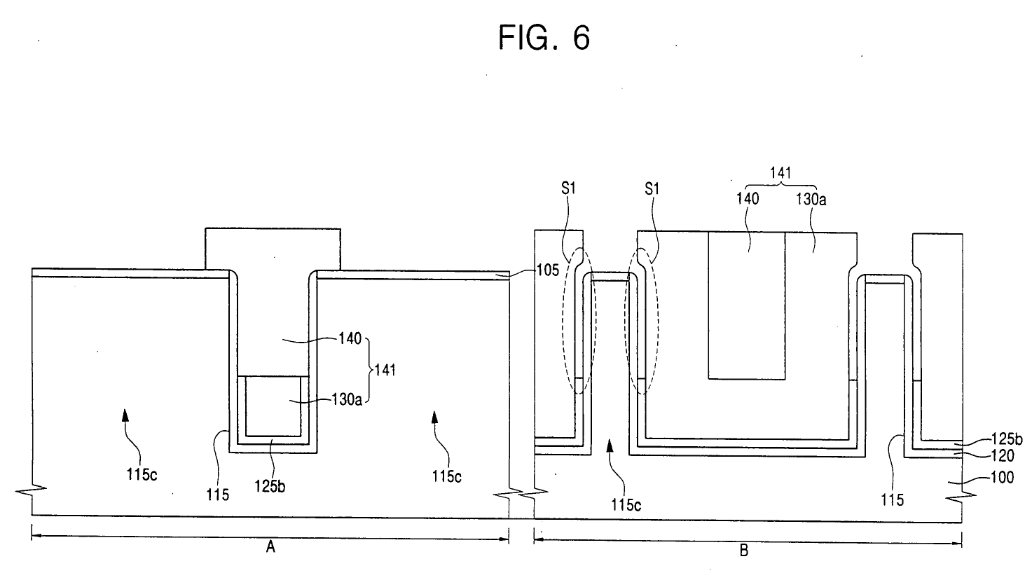

Referring to FIGS. 1 and 6, the hard masks 110 may be removed and the insulating liner 125a may be partially etched at the same time. For example, when the hard masks 110 and the insulating liner 125a are formed of silicon nitride layers, the hard masks 110 may be removed by an etching process using an etching solution containing phosphoric acid, the insulating liner 125a covering the sidewalls of the hard masks 110 may also be removed, and then the insulating liner 125a on the sidewalls of the active fins 115c substantially parallel to the major axis X may be over-etched for partially etching the insulating liner 125a. Consequently, a liner pattern 125b may be formed on the semiconductor substrate between the active fins 115c and the lower sidewalls of the active fins 115c. As a result, a first space S1, as large as a space occupied by the insulating liner 125a, may be formed on the upper sidewalls of the active fins 115c substantially parallel to the major axis X.

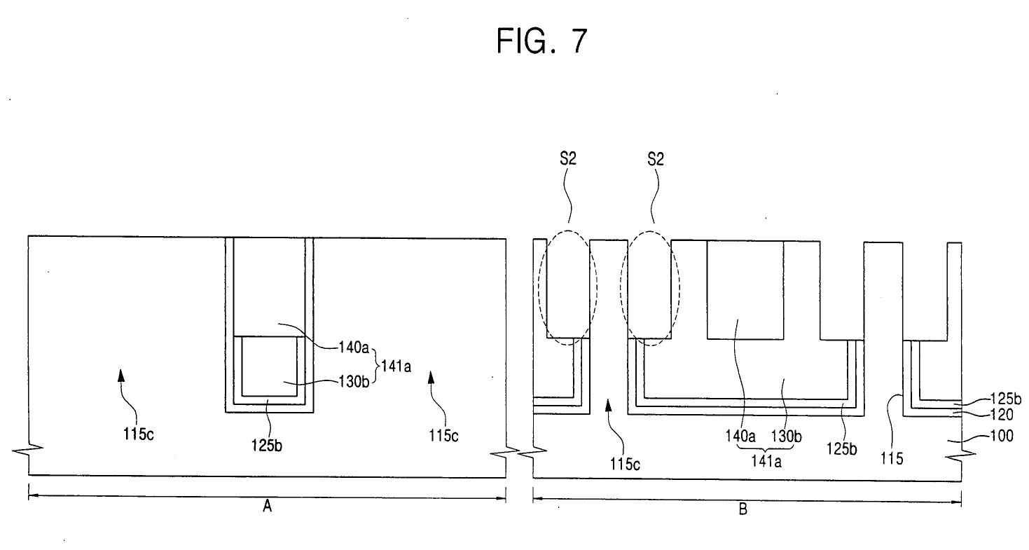

Referring to FIGS. 1 and 7, the buffer oxide layer 120 on the upper sidewalls of the active fins 115c substantially parallel to the major axis X may be removed by an isotropic etching process while the pad oxide layer 105 may be removed. Consequently, the buffer oxide layer 120 may remain on the semiconductor substrate between the active fins 115c, on the sidewalls of the active fins 115c substantially parallel to the minor axis Y, and on the lower sidewalls of the active fins 115c substantially parallel to the major axis X.

In addition, in removing the buffer oxide layer 120 covering the upper sidewalls of the active fins 115c substantially parallel to the major axis X by the isotropic etching process, the preliminary isolation layer 141 comprising the trench insulating layer 130a and the preliminary buffer insulating pattern 140 may also be isotropically etched so as to form an isolation layer 141a comprising a trench insulating pattern 130b and buffer insulating patterns 140a. Consequently, a second space S2, larger than the first space S1, may be formed between the upper sidewalls of the active fins 115c and the isolation layer 141a.

Accordingly, the isolation layer 141a disposed between the sidewalls of the active fins 115c substantially parallel to the minor axis Y may be formed to have a top surface that is substantially the same level with the top surfaces of the active fins 115c.

Referring to FIGS. 1, 8 and 9, a gate dielectric layer 150 may be formed to cover the top surfaces and the exposed sidewalls of the active fins 115c. The gate dielectric layer 150 may be formed of a thermal oxide layer or a high-k dielectric layer. In addition, gate lines 155 may be formed to cross over the active fins 115c and run on the isolation layer 141a on the semiconductor substrate having the gate dielectric layer 150. Here, the gate lines 155 crossing over the active fins 115c may be formed to cover the top surfaces and the exposed upper sidewalls of the active fins 115c. The gate lines 155 may be formed of conductive material layers. For example, the gate lines 155 may be formed of silicon layers or metal material layers.

Capping patterns 160 may be formed to cover top surfaces of the gate lines 155. Particularly, a gate conductive layer and a capping insulating layer may be sequentially formed on the semiconductor substrate having the gate dielectric layer 150 and then patterned, thereby forming the gate lines 155 and the capping patterns 160 in sequence.

Gate spaces 165 may be formed to cover the sidewalls of the gate lines 155. The gate spaces 165 may include a silicon nitride layer or a silicon oxide layer.

Impurity regions 170 may be formed in the active fins 115c disposed on both sides of the gate lines 155. Channel regions may be defined by predetermined regions of the active fins 115c between the impurity regions 170.

Accordingly, a Fin-FET (Fin Field Effect Transistor) may be composed of the impurity regions 170, the channel region between the impurity regions 170, the gate dielectric layer 150 on the channel region, and the gate line 155.

In the present invention, each of the gate lines 155 may be formed to pass through the electrically unrelated active fins 115c for ease of design and high integration. Also, each of the gate lines 155 may be formed to cross over the plurality of active fins 115c to form a circuit.

Accordingly, each of the gate lines 155 may be formed to run on the isolation layer 141a between the electrically unrelated active fins 115c, i.e., the top portion of the buffer insulating pattern 140a. Consequently, in the case of driving a semiconductor device, an electric field may be generated by the gate line 155 running on the buffer insulating pattern 140a, and the electric field may have a minimal effect on Fin-FETs formed at the active fins 115c adjacent to the buffer insulating patterns 140a. Accordingly, the electric field generated by the gate lines 155 running on the buffer insulating patterns 140a can suppress electric potential from increasing in the electrically unrelated active fins 115c. Consequently, it is possible to suppress degradation of the active fins 115c and improve the current drivability of the Fin-FETs, so that the reliability and performance of the semiconductor device can be improved.

Also, the liner pattern 125b is formed on the lower sidewalls of the active fins 115c, but not on the upper sidewalls of the active fins 115c, thereby enabling parasitic capacitance generated between different active fins 115c in which the impurity regions 170 are formed to be minimized. As a result, it is possible to minimize degradation of the performance of the semiconductor device.

A method of fabricating a semiconductor device according to another exemplary embodiment of the invention will now be described with reference to FIGS. 10 to 16. Hereinafter, a semiconductor substrate formed by the method of fabricating the semiconductor device described with reference to FIGS. 2 and 3 may be used. That is, a semiconductor substrate having the preliminary trench insulating layer 130 described with reference to FIGS. 2 and 3 is prepared. All processes up to forming the preliminary trench insulating layer 130 have been described with reference to FIGS. 2 and 3 and thus will not be described again below.

Referring to FIGS. 10 and 11, mask patterns 235a are formed on the semiconductor substrate having the preliminary trench insulating layer 130. The mask patterns 235a may be formed of photoresist patterns or hard mask patterns composed of material layers having an etch selectivity with respect to the hard mask patterns 110. For example, the hard mask patterns may be formed of polysilicon layers. The mask patterns 235a, as illustrated in FIG. 10, may be formed into a line passing the top of the preliminary trench insulating layer 130 disposed between the active fins 115c, and the top of the hard mask 110. That is, the mask patterns 235a may be formed to cross sidewalls of the active fins 115c substantially parallel to the major axis X, to cross over the active fins 115c, and to pass the top of the preliminary trench insulating layer 130 disposed between the sidewalls of the active fins 115c substantially parallel to the minor axis Y. As a result, a top surface of the preliminary insulating liner 125 formed between the preliminary trench insulating layer 130 and the sidewalls of the hard masks 110 substantially parallel to the minor axis Y may be exposed by the mask patterns 235a.

When the mask patterns 235a are formed of hard mask patterns such as silicon layers, the formation of the mask patterns 235a may include forming preliminary mask patterns 235 having a first width W1 on the semiconductor substrate having the preliminary trench insulating layer 130 and then isotropically etching the preliminary mask patterns 235. Consequently, the mask patterns 235a may be formed to have a second width W2 narrower than the first width W1. Finally, the mask patterns 235a may be formed to have a narrower line width than a width corresponding to the resolution limit of the photolithography process.

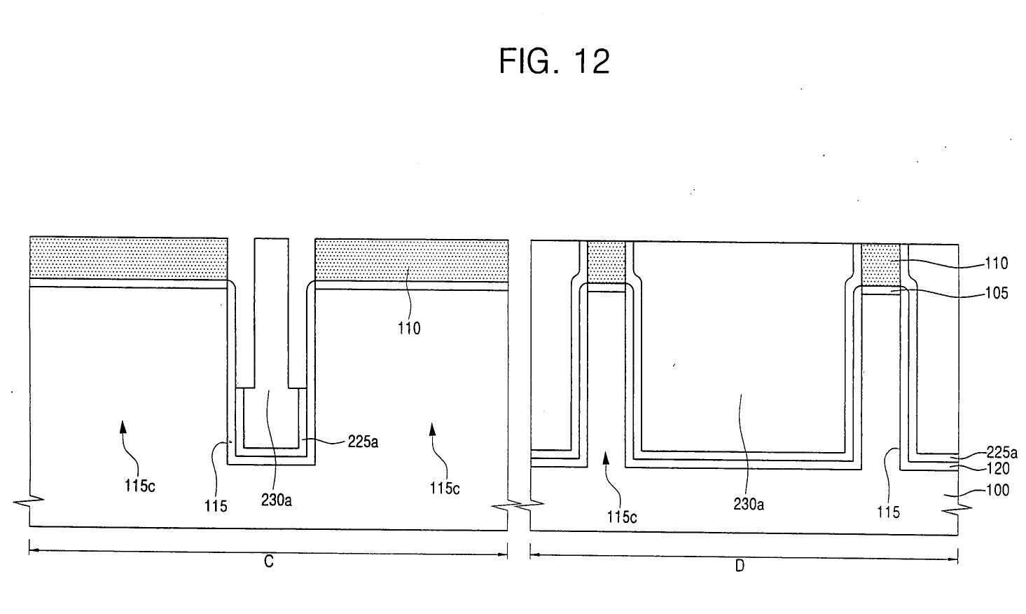

Referring to FIGS. 10 and 12, the preliminary trench insulating layer 130 may be partially etched using the mask patterns 235a and the hard masks 110 as etch masks, thereby forming a trench insulating layer 230a. As a result, a predetermined region of the preliminary insulating liner (125 in FIG. 11) on the active fins 115c may be exposed.

The mask patterns 235a may be removed. Subsequently, the exposed preliminary insulating liner (125 in FIG. 11) may be removed by an isotropic etching process using the trench insulating layer 230a as an etch mask, thereby forming an insulating liner 225a.

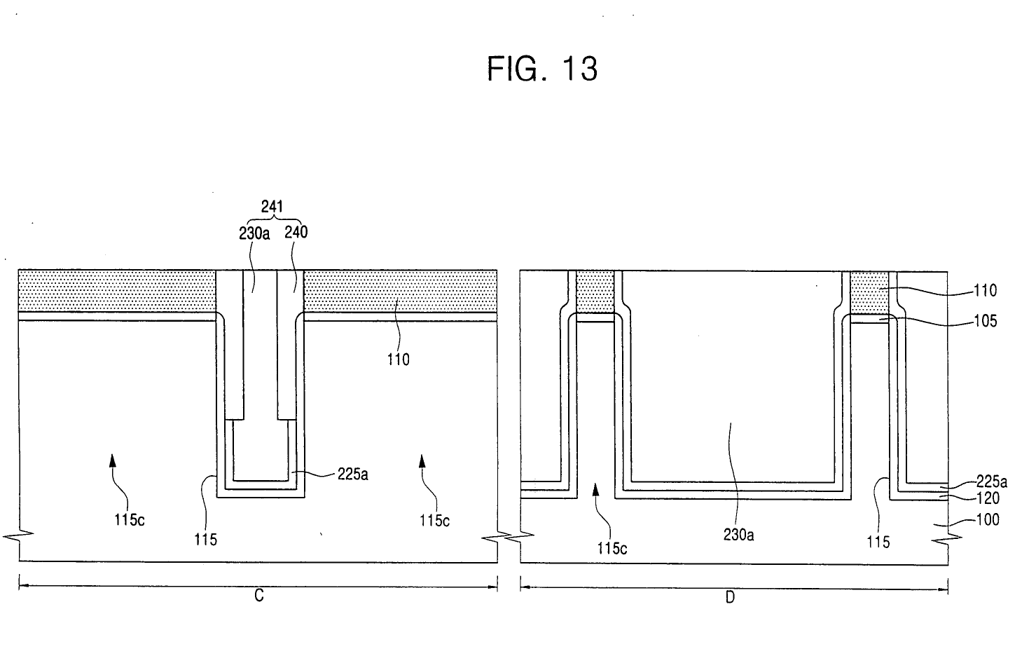

Referring to FIGS. 10 and 13, a buffer insulating layer may be formed on the semiconductor substrate having the insulating liner 225a and then planarized until the top surfaces of the hard masks 110 are exposed, so as to enable formation of a preliminary buffer insulating pattern 240. The preliminary buffer insulating pattern 240 may be formed of a material layer substantially the same as the trench insulating layer 230a. For example, when the trench insulating layer 230a may be formed of a silicon oxide layer, the preliminary buffer insulating pattern 240 may also be formed of a silicon oxide layer. As a result, a preliminary isolation layer 241 may be formed of the trench insulating layer 230a and the preliminary buffer insulating pattern 240.

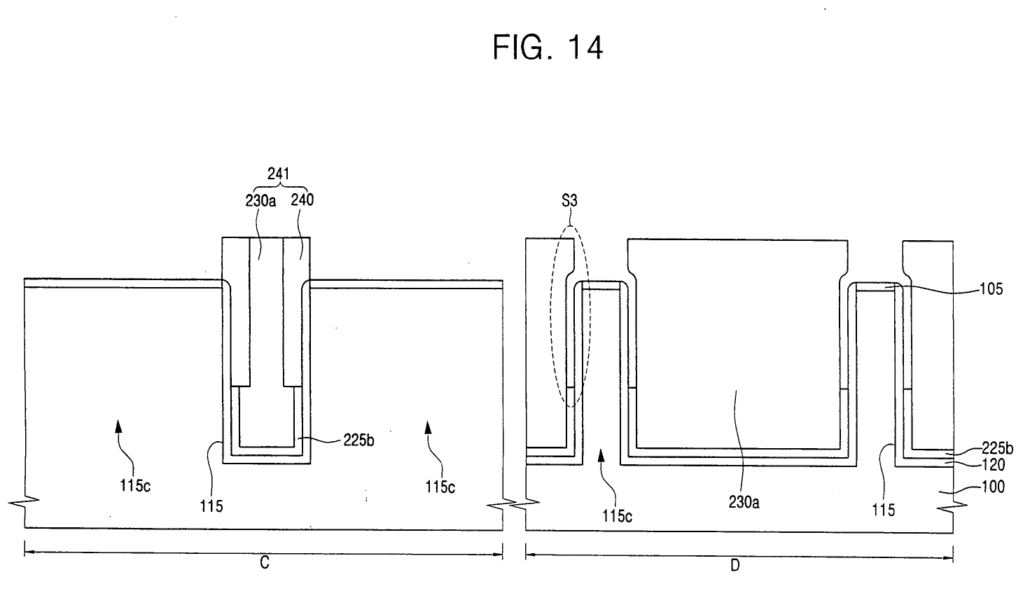

Referring to FIGS. 10 and 14, the hard masks (110 in FIG. 13) may be removed. Specifically, the hard masks (110 in FIG. 13) may be removed by an etching process using the preliminary isolation layer 241 as an etch mask. Further, the insulating liner (225a in FIG. 13) may be exposed by removing the hard masks (110 in FIG. 13) and partially etched, thereby forming a liner pattern 225b. Particularly, when the hard masks (110 in FIG. 13) and the insulating liner (225a in FIG. 13) are formed of equivalent material layers, while the hard masks (110 in FIG. 13) are removed by the etching process using the preliminary isolation layer 241 as an etch mask, a part of the insulating liner (225a in FIG. 13) may be also etched, and the insulating liner (225a in FIG. 13) on upper sidewalls of the active fin 115c may be over-etched, thereby forming a liner pattern 225b. As a result, the liner pattern 225b may be formed on the semiconductor substrate between the active fins 115c and on lower sidewalls the active fins 115c. Also, the insulating liner (225a in FIG. 13) may be partially etched, thereby forming a third space S3 between the preliminary isolation layer 241 and the upper sidewalls of the active fins 115c substantially parallel to the major axis X. Here, a predetermined region of the buffer oxide layer 120 covering an inner wall of the trench 115 may be exposed by the third space S3. Also, the pad oxide layers 105 may be exposed.

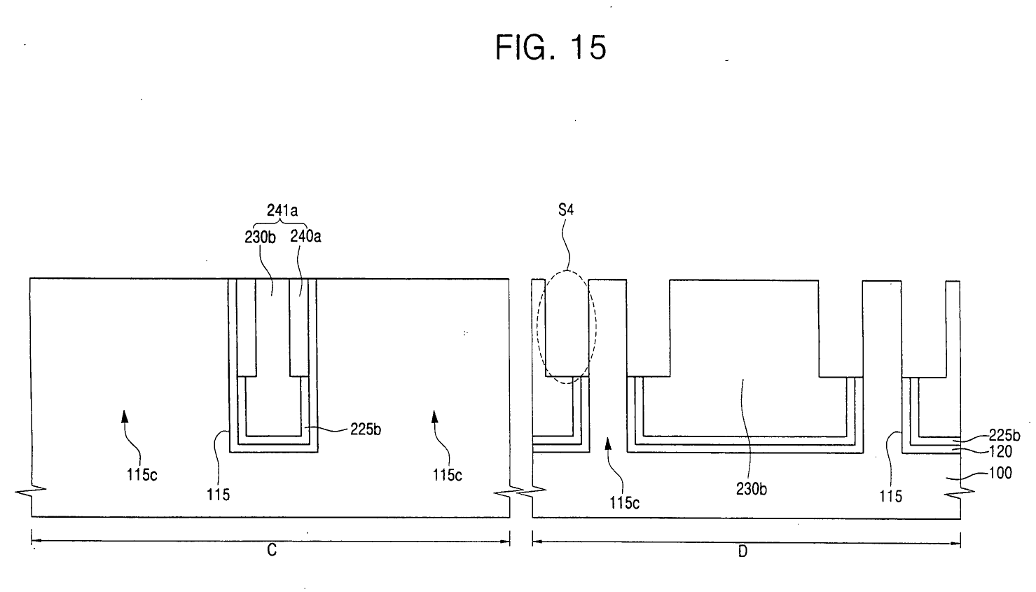

Referring to FIGS. 10 and 15, the exposed buffer oxide layer 120 and the exposed pad oxide layers 105 may be removed by an isotropic etching process. Here, while the exposed buffer oxide layer 120 and the exposed pad oxide layers 105 are removed by the isotropic etching process, the preliminary isolation layer 241 composed of the trench insulating layer 230a and the preliminary buffer insulating pattern 240 may also be isotropically etched so as to form an isolation layer 241a composed of a trench insulating pattern 230b and a buffer insulating pattern 240a. Also, while the exposed buffer oxide layer 120 and the exposed pad oxide layers 105 are isotropically etched, the third space S3 may expand to form a fourth space S4. Here, the isolation layer 241a may have a top surface that is substantially the same level with the top surfaces of the active fins 115c.

Accordingly, parts of the sidewalls of the active fins 115c that are substantially parallel to the major axis X and the top surfaces of the active fins 115c may be exposed by the fourth space S4.

As illustrated in FIG. 10, at least two mask patterns 235a, which are shown in FIGS. 10 and 11, may be formed to cross over a single active fin. Here, when the two mask patterns 235a cross over the single active fin, looking at one of the sidewalls of the active fins 115c substantially parallel to the major axis X, as many fourth spaces S4 as the number of the mask patterns 235a may be formed and spaced apart by the isolation layer 241.

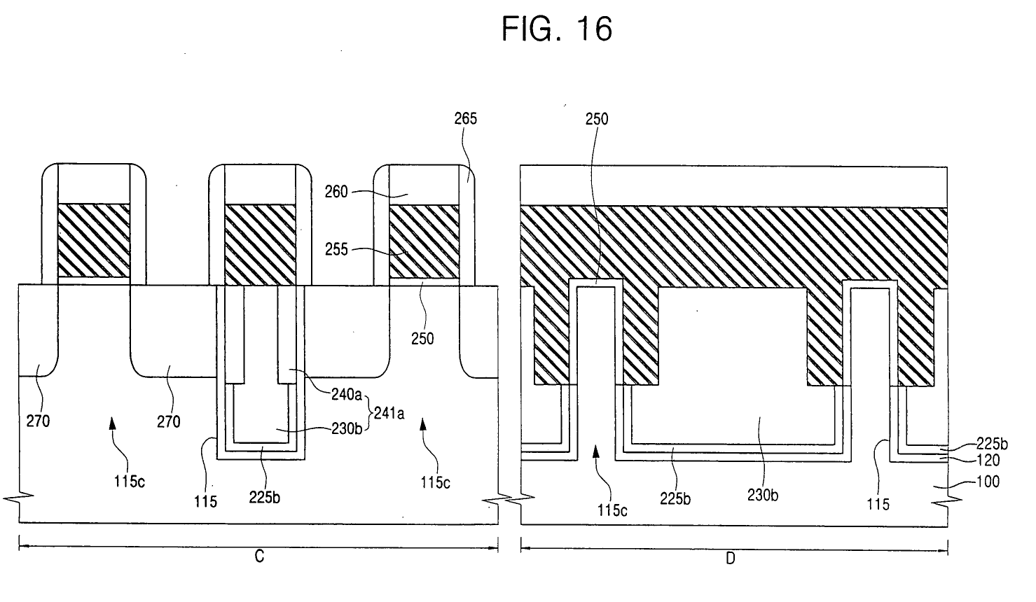

Referring to FIGS. 10 and 16, a gate dielectric layer 250 may be formed to cover the top surfaces and the exposed sidewalls of the active fins 115c. The gate dielectric layer 250 may be formed of a thermal oxide layer or a high-k dielectric layer. Gate lines 255 are crossing over the active fins 115c and running on the isolation layer 241a are formed on the semiconductor substrate having the gate dielectric layer 250. Here, the gate lines 255 crossing over the active fins 115c may be formed to cover the top surfaces and the exposed upper sidewalls of the active fins 115c. Further, each gate line 255 may be formed to fill the fourth space S4. Capping patterns 260 may be formed to cover the top surfaces of the gate lines 255, and gate spacers 265 may be formed to cover sidewalls of the gate line 255.

Impurity regions 270 may be formed in the active fins 115c at both sides of the gate lines 255. The active fins 115c between the impurity regions 270 may be defined as a channel region. Accordingly, the impurity regions 270, the channel region between the impurity regions 270, the gate dielectric layer 250 on the channel region, and the gate line 255 may constitute a Fin-FET.

As a result, when a semiconductor device is driven, an electric field generated by the gate lines 255 running on the isolation layer 241a disposed between the sidewalls of the active fins 115c substantially parallel to the minor axis Y may have a minimal effect on the Fin-FETs formed at the active fins 115c adjacent to the isolation layer 241a. Accordingly, the electric field generated by the gate lines 255 running on the isolation layer 241a disposed between the sidewalls of the active fins 115c substantially parallel to the minor axis Y can prevent an increase in the electric potential in the electrically unrelated active fins 115c. Consequently, it is possible to prevent deterioration in performance of the Fin-FETs and improve the current drivability of the Fin-FETs, so that the reliability and performance of the semiconductor device can be improved.

In the invention, the liner patterns 125b and 225b are formed on the semiconductor substrate between the active fins 115c and on the lower sidewalls of the active fins 115c, and the predetermined regions of the upper sidewalls of the active fins 115c are covered with the isolation layers 141a and 241a, so that parasitic capacitance generated between adjacent active fins can be minimized. In other words, in line with trends toward high integration in semiconductor devices, the distance between adjacent active fins 115c becomes narrow in El and E2 regions which are illustrated in FIGS. 1 and 10, respectively. As a result, only the isolation layers 141a and 241a are formed between the impurity regions 170 in the active fins 115c of the El and E2 regions illustrated in FIGS. 1 and 10, respectively, so that there is no conventional liner composed of a silicon nitride layer formed to cover the inner wall of the trench. Thereby, parasitic capacitance between the impurity regions 170 in the active fins 115c can be minimized.

Moreover, the liner patterns 125b and 225b may serve to protect the semiconductor substrate between the active fins 115c and the lower sidewalls of the active fins 115c from thermal stress in following processes.

A semiconductor device according to exemplary embodiments of the invention will now be described with reference to FIGS. 1, 8 and 9.

Referring to FIGS. 1, 8 and 9, a semiconductor device includes a plurality of active fins 115c disposed on a semiconductor substrate 100. The plurality of active fins 115c is two-dimensionally arrayed in directions of a major axis X and a minor axis Y on the semiconductor substrate 100. The semiconductor substrate 100 may be a semiconductor substrate. Also, the active fins 115c may be semiconductor fins. For example, each active fin 115c may be a silicon fin.

An isolation layer 141a surrounding the active fins 115c is provided to partially expose sidewalls of the active fins 115c substantially parallel to the major axis X. The isolation layer 141a may be composed of a trench insulating pattern 130b and a buffer insulating pattern 140a.

The trench insulating pattern 130b may fill a space between the active fins 115c to partially expose the sidewalls of the active fins 115c substantially parallel to the major axis X and have recessed holes exposing upper sidewalls of the active fins 115c substantially parallel to the minor axis Y between the sidewalls of the active fins substantially parallel to the minor axis Y. The buffer insulating patterns 140a may fill the recessed holes. The trench insulating pattern 130b and the buffer insulating patterns 140a are formed of substantially the same material layer. For example, when the trench insulating pattern 130b may be formed of a silicon oxide layer, the buffer insulating patterns 140a may also be formed of silicon oxide layers. The isolation layer 141a disposed between the sidewalls of the active fins 115c substantially parallel to the minor axis Y may have a top surface disposed at substantially the same level as the top surfaces of the active fins 115c.

A liner pattern 125b is interposed between the semiconductor substrate between the active fins 115c and the isolation layer 141a, and between lower sidewalls of the active fins 115c and the isolation layer 141a. The liner pattern 125b may be formed of a silicon nitride layer.

Gate lines 155 are provided to cover the exposed sidewalls of the active fins 115c and the top of the active fins 115c, to cross over the active fins 115c and extend toward the isolation layer 141a. Each gate line 155 may be disposed to run on the electrically related active fins 115c and on the isolation layer 141a between the electrically unrelated active fins 115c. The gate lines 155 may be formed of conductive material layers. For example, the gate lines 155 may be formed of silicon layers or metal material layers.

A gate dielectric layer 150 may be interposed between the gate lines 155 and the active fins 115c. The gate dielectric layer 150 may include a silicon oxide layer or a high-k dielectric layer.

Impurity regions 170 may be provided in the active fins 115c at both sides of the gate lines 155. That is, the impurity regions 170 may be disposed to be spaced apart from each other in the single active fin 115c. Here, a single active fin 115c disposed between the spaced-apart impurity regions 170 may be defined as a channel region. Accordingly, for a single active fin 115c, the gate line 155 crossing over the channel region may be defined as a gate electrode, and the impurity regions 170 that are spaced apart on either side of the channel region may be defined as source and drain regions. As a result, a Fin-FET device may be provided.

The liner pattern 125b may be provided on the semiconductor substrate between the active fins 115c and the lower sidewalls of the active fins 115c. Also, the impurity regions 170 may be provided in upper regions of the active fins 115c. Therefore, the isolation layer 141a may be disposed between the impurity regions 170 in adjacent active fins 115c so that parasitic capacitance between adjacent active fins 115c can be minimized. That is, three active fins 115c are disposed in the El region illustrated in FIG. 1. The impurity regions 170 provided in the active fins 115c in the El region are adjacent to both sides of the isolation layer 141a, respectively. As integration density increases, a distance between the impurity regions 170 in the El region narrows. However, the resulting parasitic capacitance between the impurity regions 170 of the El region can be minimized because the liner pattern 125b composed of a silicon nitride layer is not disposed on the upper sidewalls of the active fins 115c but the isolation layer 141a composed of a silicon oxide layer is disposed between the upper sidewalls of the active fins 115c. Also, the liner pattern 125b serves to protect the lower sidewalls of the active fins 115c and the semiconductor substrate between the active fins 115c from thermal stress in following processes.

A semiconductor device according to other exemplary embodiments of the invention will now be described with reference to FIGS. 10 and 16.

Referring to FIGS. 10 and 16, a semiconductor device includes the active fins 115c as shown in FIGS. 1, 8 and 9. An isolation layer 241a surrounding the active fins 115c is provided to partially expose sidewalls of the active fins 115c substantially parallel to the major axis X. The isolation layer 241a may be composed of a trench insulating pattern 230b and buffer insulating patterns 240a. The isolation layer 241a disposed between the sidewalls of the active fins 115c substantially parallel to the minor axis Y may be formed of the buffer insulating patterns 240a covering the upper sidewalls of the active fins 115c substantially parallel to the minor axis Y and the trench insulating pattern 230b interposed between the buffer insulating patterns 240a and between the lower sidewalls of the active fins 115c substantially parallel to the minor axis Y Also, the isolation layer 241 a disposed between the sidewalls of the active fins 115c substantially parallel to the major axis X may be composed of the buffer insulating patterns 240a interposed between the upper sidewalls of the active fins 115c substantially parallel to the major axis X except predetermined regions of the upper sidewalls of the active fins 115c which are covered with a gate lines 255, and the trench insulating pattern 230b interposed between the lower sidewalls of the active fins 115c substantially parallel to the major axis X and between the buffer insulating patterns 240a at the same time. The buffer insulating patterns 240a and the trench insulating pattern 230b may be formed of substantially the same material layer. For example, the buffer insulating patterns 240 a and the trench insulating pattern 230b may be formed of silicon oxide layers.

The semiconductor device according to exemplary embodiments of the invention described with reference to FIGS. 1, 8 and 9, may include a liner pattern 225b, gate lines 255, impurity regions 270 and a gate dielectric layer 250 corresponding to the liner pattern 125b, the gate lines 155, the impurity regions 170 and the gate dielectric layer 150, respectively. As a result, a Fin-FET that is substantially the same as described with reference to FIGS. 1, 8 and 9 can be provided.

According to the present invention as described above, an isolation layer that defines active fins two-dimensionally arrayed in directions of major and minor axes, may be provided. The isolation layer disposed between sidewalls of the active fins substantially parallel to the minor axis may be provided so that its top surface is substantially level with top surfaces of the active fins. An electric field generated by a gate line running on the isolation layer between the sidewalls of the active fins substantially parallel to the minor axis may suppress an increase in electric potential in electrically unrelated active fins. As a result, it is possible to prevent deterioration in performance of Fin-FETs, thereby enhancing the reliability and performance of the semiconductor device.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a semiconductor device, comprising:
preparing a semiconductor substrate;
forming a plurality of active fins having major and minor axes and two-dimensionally arrayed on the semiconductor substrate in directions of the major and minor axes;
forming a liner pattern on lower sidewalls of the active fins;
forming an isolation layer on the semiconductor substrate having the liner pattern, the isolation layer exposing top surfaces of the active fins and a part of the active fins' sidewalls substantially parallel to the major axis; and
forming gate lines parallel to each other to cover the top surfaces and the exposed sidewalls of the active fins, cross over the active fins, and run on the isolation layer.

2. The method according to claim 1, wherein forming the liner pattern comprises:
forming a preliminary insulating liner on the semiconductor substrate having the active fins;
forming a preliminary trench insulating layer surrounding the active fins on the semiconductor substrate having the preliminary insulating liner;
partially etching the preliminary trench insulating layer disposed between the sidewalls of the active fins parallel to the minor axis, thereby forming a trench insulating layer having a hole exposing a predetermined region of the preliminary insulating liner;
removing the exposed preliminary insulating liner, thereby forming an insulating liner exposing upper sidewalls of the active fins substantially parallel to the minor axis;
forming a preliminary buffer insulating pattern to fill a space between the upper sidewalls of the active fins substantially parallel to the minor axis on the semiconductor substrate having the insulating liner; and
partially etching the insulating liner using the trench insulating layer and the preliminary buffer insulating pattern as etch masks.

3. The method according to claim 2, wherein forming the trench insulating layer comprises:
forming a mask pattern having an opening which exposes the preliminary trench insulating layer disposed between the sidewalls of the active fins substantially parallel to the minor axis on the semiconductor substrate having the preliminary trench insulating layer;
partially etching the exposed preliminary trench insulating layer using the mask pattern as an etch mask; and
removing the mask pattern.

4. The method according to claim 2, wherein forming the isolation layer comprises isotropically etching the trench insulating layer and the preliminary buffer insulating pattern.

5. The method according to claim 1, wherein forming the liner pattern comprises:
forming a preliminary insulating liner on the semiconductor substrate having the active fins;
forming a preliminary trench insulating layer surrounding the active fins on the semiconductor substrate having the preliminary insulating liner;
partially etching the preliminary trench insulating layer, thereby forming a trench insulating layer exposing the preliminary insulating liner disposed on upper sidewalls of the active fins substantially parallel to the minor axis and a part of the sidewalls of the active fins substantially parallel to the major axis;
removing the exposed preliminary insulating liner and forming an insulating liner exposing predetermined regions of the sidewalls of the active fins;
forming a preliminary buffer insulating pattern to cover the exposed sidewalls of the active fins on the semiconductor substrate having the insulating liner; and
partially etching the insulating liner using the preliminary buffer insulating pattern and the trench insulating liner as etch masks.

6. The method according to claim 5, wherein forming the trench insulating layer comprises:
forming parallel mask patterns to cross the sidewalls of the active fins substantially parallel to the major axis on the semiconductor substrate having the preliminary trench insulating layer, cross over the active fins, and run on the preliminary trench insulating layer disposed on the sidewalls of the active fins substantially parallel to the minor axis;
partially etching the preliminary trench insulating layer using the mask patterns as etch masks; and
removing the mask patterns.

7. The method according to claim 5, wherein the mask patterns are formed of photoresist patterns or hard mask patterns.

8. The method according to claim 7, wherein forming the mask patterns from hard mask patterns comprises:
forming preliminary hard mask patterns to have a first width on the semiconductor substrate having the preliminary trench insulating layer; and
isotropically etching the preliminary hard mask patterns, thereby forming the mask patterns to have a smaller width than the first width.

9. The method according to claim 5, wherein forming the isolation layer comprises isotropically etching the preliminary buffer insulating pattern and the trench insulating layer.

10. The method according to claim 1, wherein the isolation layer is formed of a material layer having an etch selectivity with respect to the liner pattern.

11. The method according to claim 10, wherein the liner pattern is formed of a silicon nitride layer, and the isolation layer is formed of a silicon oxide layer.

12. The method according to claim 1, further comprising, after forming the active fins, forming a buffer oxide layer covering the sidewalls of the active fins,
wherein the buffer oxide layer covering upper sidewalls of the active fins substantially parallel to the major axis is removed in forming the isolation layer.

13. The method according to claim 1, wherein the isolation layer disposed between the sidewalls of the active fins substantially parallel to the minor axis is formed to have a top surface on substantially the same level as the top surfaces of the active fins.

14. The method according to claim 1, further comprising, before forming the gate line, forming a gate dielectric layer to cover the top surfaces and the exposed sidewalls of the active fins.

15. A method of fabricating a semiconductor device, comprising:
forming a plurality of active fins on a semiconductor substrate;
forming a liner pattern surrounding lower sidewalls of the active fins;
forming a gate dielectric layer surrounding higher sidewalls of the active fins, the gate dielectric layer covering the top surfaces of the active fins;
forming an isolation layer on the liner pattern;
forming gate lines on the gate dielectric layer, the gate lines crossing over the active fins and extended to the top of the isolation layer.

16. The method according to claim 15, wherein some portions of the gate lines are interposed between the gate dielectric layer and the isolation layer.

17. The method according to claim 15, further comprising forming a buffer oxide layer between the lower sidewalls of the active fins and the liner pattern.

18. The method according to claim 15, wherein the isolation layer is formed of a trench insulating pattern and a buffer insulating pattern, the trench insulating pattern disposed below the buffer insulating pattern.

19. The method according to claim 18, wherein a portion of the buffer insulating pattern contacts with the liner pattern and the gate lines.

20. The method according to claim 15, wherein the isolation layer is formed of a silicon oxide layer.

21. The method according to claim 15, wherein the liner pattern is formed of a silicon nitride layer.

22. A semiconductor device, comprising:
a semiconductor substrate;
a plurality of active fins having major and minor axes and two-dimensionally arrayed on the semiconductor substrate in directions of the major and minor axes;
an isolation layer surrounding the active fins and exposing top surfaces of the active fins and a part of the active fins' sidewalls substantially parallel to the major axis;
a liner pattern interposed between lower sidewalls of the active fins and the isolation layer; and
gate lines covering the top surfaces of the active fins and the exposed sidewalls of the active fins, crossing over the active fins, and extended to the top of the isolation layer.

23. The device according to claim 22, wherein the isolation layer is formed of a trench insulating pattern and a buffer insulating pattern, the trench insulating pattern partially exposing the sidewalls of the active fins substantially parallel to the major axis and filling spaces between the active fins to have recessed holes which expose upper sidewalls of the active fins substantially parallel to the minor axis between the sidewalls of the active fins substantially parallel to the minor axis, the buffer insulating pattern filling the recessed holes.

24. The device according to claim 22, wherein the isolation layer disposed between the sidewalls of the active fins substantially parallel to the minor axis is composed of buffer insulating patterns covering upper sidewalls of the active fins substantially parallel to the minor axis, and a trench insulating pattern interposed between the buffer insulating patterns and between the lower sidewalls of the active fins substantially parallel to the minor axis.

25. The device according to claim 22, wherein the isolation layer disposed between the sidewalls of the active fins substantially parallel to the minor axis has a top surface on substantially the same level as the top surfaces of the active fins.

26. The device according to claim 22, wherein the isolation layer is formed of a silicon oxide layer and the liner pattern is formed of a silicon nitride layer.

27. The device according to claim 22, further comprising a gate dielectric layer interposed between the active fins and the gate line.

28. A semiconductor device, comprising:
a plurality of active fins on a semiconductor substrate;
a liner pattern surrounding lower sidewalls of the active fins;
a gate dielectric layer surrounding higher sidewalls of the active fins, the gate dielectric layer covering the top surfaces of the active fins;
an isolation layer on the liner pattern;
gate lines on the gate dielectric layer, the gate lines crossing over the active fins and extended to the top of the isolation layer.

29. The device according to claim 28, wherein some portions of the gate lines are interposed between the gate dielectric layer and the isolation layer.

30. The device according to claim 28, further comprising a buffer oxide layer interposed between the lower sidewalls of the active fins and the liner pattern.

31. The device according to claim 28, wherein the isolation layer is formed of a trench insulating pattern and a buffer insulating pattern, the trench insulating pattern disposed below the buffer insulating pattern.

32. The device according to claim 31, wherein a portion of the buffer insulating pattern contacts with the liner pattern and the gate lines.

33. The device according to claim 28, wherein the isolation layer is formed of a silicon oxide layer.

34. The device according to claim 28, wherein the liner pattern is formed of a silicon nitride layer.
